(19) United States
(12) Patent Application Publication
(10) Pub. No.: US 2001/0010087 A1
(43) Pub. Date: Jul. 26, 2001

(54) Method of analyzing fault occurring in semiconductor device

(76) Inventor: Mikio Tanaka, Tokyo (JP)

Correspondence Address: McGinn & Gibb, PLLC, 8321 Old Courthouse Road, Suite 200, Vienna, VA, 22182-3817, US

(21) Appl. No.: 09/764,453

(22) Filed: Jan. 19, 2001

(30) Foreign Application Priority Data
Jan. 21, 2000 (JP) 12753-2000

(51) Int. Cl. G01R 31/28

(52) U.S. Cl. 714/724

(57) ABSTRACT

To analyze faults occurring in a semiconductor device, an expectation function is derived from bitmap data produced by a tester which is for the semiconductor device. The expectation function represents a distribution of the fault bits and has factors including a predetermined factor. On the basis of the expectation function, it is judged whether or not the distribution of the fault bits has a regular profile. If the distribution of fault bits has a regular profile, by the use of the predetermined factor, a period of the regular profile is automatically provided as an additional parameter to interpret the regular profile and to identify what causes the faults.

### BACKGROUND OF THE INVENTION

This invention relates to an analyzing method of faults occurring in a semiconductor device where a plurality of circuitry elements are arranged regularly. Such semiconductor device is, for example, a memory device (or a memory LSI), a liquid crystal panel, or the like. This invention also relates to a fault analyzer which carries out the analyzing method, and to a computer program product for enabling a processor to execute the analyzing method.

In general, during the production process of semiconductor devices, each of the products is subjected to a test to judge whether the product is a reject or not. A tester is used in the test for electrically testing semiconductor devices and produces bitmap data as a test result.

Faults occurring in a semiconductor device are represented as fault bits in bitmap data. If semiconductor device has a plurality of circuitry elements arranged regularly, a source of the faults might be figured out by a distribution of fault bits. For example, if the distribution of fault bits has a regular profile, it is presumed that an error exists on the design. If not, the faults are presumed to be caused by, for example, contamination occurred in the manufacture process.

As for a distribution of fault bits in bitmap data, various kind of analyzing methods have been proposed. For example, such methods are disclosed in Japanese Unexamined Patent Publications (JP-A) Nos. Hei 7-72206, Hei 7-221156, Hei 9-270012, Hei 11-186354, and 2000-200814. Japanese Patent Application No. Hei 11-130709 also discloses an analyzing method relating to a distribution of fault bits. The above-mentioned publications and the disclosure of the application are incorporated herein by reference.

As mentioned above, a memory LSI, a liquid crystal panel, and the like, are the types of semiconductor devices each of which has a plurality of circuitry elements arranged regularly. As the technology in the semiconductor field rapidly progresses, capacity of a memory LSI has acceleratingly become large as well as its density has become high. A liquid crystal panel has also become large in size. Moreover, the diameter of wafer trends to increase up to 300 mm, It is no doubt that the above-mentioned improvements will cause the analyzed objects, namely, the number of bits in bitmap data to be increased.

The increase of the number of bits in bitmap data also brings about a large amount of analyses results in accordance with the above-mentioned analyzing methods. It is therefore required to automatically provide an additional parameter to easily interpret the analyses results.

### SUMMARY OF THE INVENTION

This invention therefore provides an analyzing method which, when a distribution of fault bits has a regular profile, automatically provide a period of the regular profile as an additional parameter to interpret the regular profile.

According to one aspect of this invention, a method of analyzing faults occurring in a semiconductor device uses bitmap data produced as a test result by a tester which is for the semiconductor device. The tester comprises a first memory to store the bitmap data. The semiconductor device comprises circuitry elements which are arranged regularly in the semiconductor device. Each of the circuitry elements correspond to bits in the bitmap data, respectively. The bits have addresses to indicate locations of the bits in the bitmap data. The bits of the bitmap data include fault bits which correspond to the circuitry elements having the faults.

The analyzing method according to one aspect of the present invention is executed in a computer system including a second memory and comprises the following steps of;

defining and initializing a plurality of difference emergence values, so that all of the difference emergence values have zeros as initial values and are stored in the second memory;

reading the bitmap data out of the first memory to write into the second memory coordinate values of all of the fault bits included in the bitmap data;

selecting a pair of the fault bits from all of the fault bits to calculate a difference value between the addresses of the pair of fault bits, with reference to the coordinate values written into the second memory;

adding one to the difference emergence value related to the difference value which is obtained as a result of the calculation in the selecting, so that the difference emergence value is updated and stored in the second memory;

repeatedly executing the selecting and the adding until all pairs of the fault bits are completely processed, so that the difference emergence values indicate the numbers of times the difference values emerge in calculation results in the selecting repeatedly executed; then

deriving from all of the difference emergence values an expectation function which represents a distribution of the fault bits;

judging, on the basis of the expectation function, whether or not the distribution of the fault bits has a regular profile; and

calculating a period of the regular profile on the basis of the expectation function when the distribution has the regular profile.

The method may be in the form of software instructions and may be executed on a computer system that comprises a processor and a memory.

### BRIEF DESCRIPTION OF THE DRAWINGS

FIG. 1 is a block diagram schematically showing a fault analyzer according to a preferred embodiment of the present invention;

FIG. 2 is a flowchart showing an analyzing method which is carried out by the fault analyzer illustrated in FIG. 1;

FIG. 3 is a view showing an example of an arrangement of fault bits;

FIG. 4 is a view showing an expectation function in relation to the arrangement of fault bits illustrated in FIG. 3;

FIG. 5 is a flowchart showing a concrete example of processes in step 7 depicted in FIG. 2;

FIG. 6 is a flowchart showing a concrete example of processes in step 8 depicted in FIG. 2;

FIG. 7 is a flowchart showing another concrete example of processes in step 8 depicted in FIG. 2;

FIG. 8 is a flowchart showing another concrete example of processes in step 7 depicted in FIG. 2; and

FIG. 9 is a flowchart showing another concrete example of processes in step 8 depicted in FIG. 2

### DESCRIPTION OF THE PREFERRED EMBODIMENTS

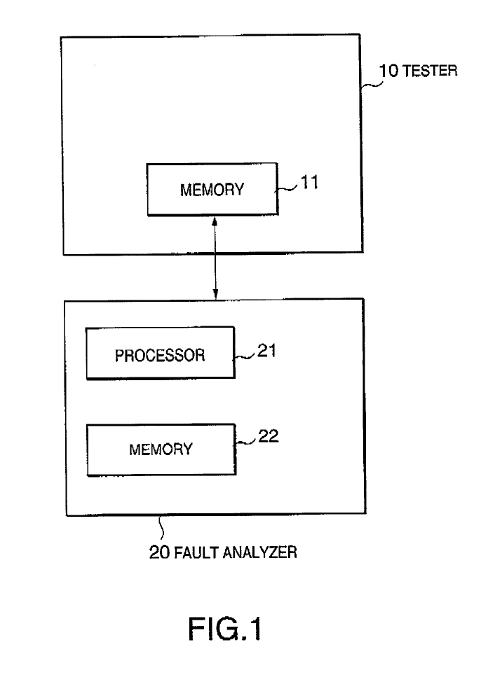

Now, preferred embodiments will be described in detail with reference to the drawings for better understanding of the present invention, Referring to FIG. 1, a fault analyzer 20 according to a preferred embodiment of the present invention analyzes faults occurring in a semiconductor device by the use of bitmap data produced as a test result by a tester 10. The tester 10 is for electrically testing the semiconductor device and comprises a memory 11 for storing the bitmap data as the test result of the semiconductor device, In the semiconductor device, a plurality of circuitry elements are arranged regularly. The circuitry elements correspond to bits having addresses in the bitmap data, respectively. The bits comprising the bitmap data include fault bits corresponding to the circuitry elements having the faults,

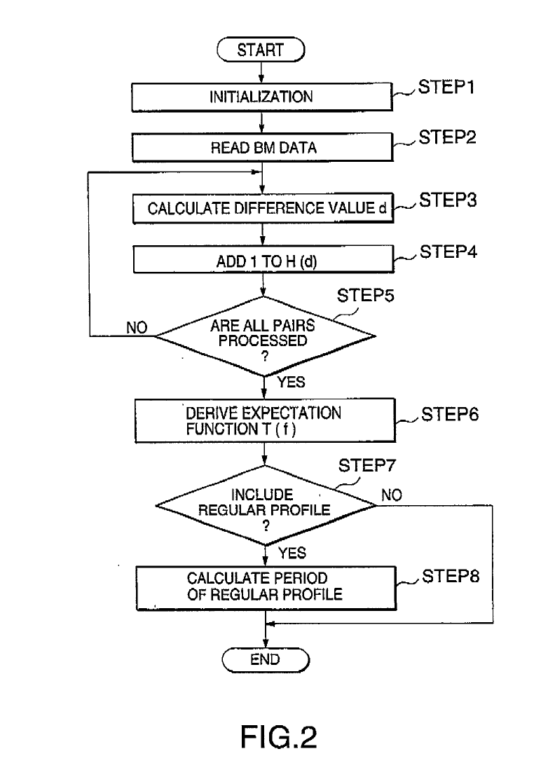

The illustrated fault analyzer 20 comprises a processor 21 and a memory 22. The fault analyzer 20 may comprise an input device, a display, I/O interface and various kinds of other computer components though these are omitted in FIG. 1 for the sake of simplicity. The illustrated memory 22 includes software instructions adapted to enable the processor 21 to drive the fault analyzer 20 for executing an analyzing method as which will be described in later with reference to FIG. 2. In other words, the illustrated processor 21 always performs in accordance with the software instructions included in the illustrated memory 22. The illustrated memory 22 is further adapted to store data processed and/or to be processed by the processor 21. The memory 22 comprises, for example, an integrated circuit and a hard disk drive.

In the illustrated fault analyzer 20, the processor 21 works as illustrated in FIG. 2.

When starting, the processor 21 carries out an initialization (Step 1) In this embodiment, the initialization includes defining and initializing a plurality of difference emergence values. The difference emergence values are variables used in the analyzing method, and are also called histograms H(d). As the result of the initialization, all of the histograms H(d) have zeros as initial values and are stored in the memory 22.

The processor 21 reads the bitmap data out of the memory 11 of the tester 10 (Step 2). As mentioned above, if the tested semiconductor device has fault elements, the bitmap data includes fault bits corresponding to the fault elements, The location of each fault bit is specified by the address of the fault bit or a coordinate value of the fault bit in the bitmap data. To use the locations of fault bits in the following steps, the processor 21 writes coordinate values of all of the fault bits into the memory 22.

Then the processor 21 selects a pair of the fault bits from all of the fault bits and calculates a difference value between the addresses of the pair of fault bits with reference to the coordinate values written in the memory 22 (Step 3). A difference value is represented by “d” and is also called “distance.” The way to calculate the difference value depends upon the kinds of analyses. For example, in the fault analysis of the X-address, the difference value is calculated so as to be an absolute value of a difference between X-coordinate values of the pair of fault bits. Provided that the X-coordinate values of fault bits is a(x) and b(x), the difference d|_{a,b}=|a(x)−b(x)|. Similarly, in the fault analysis of the Y-address, provided that the X-coordinate values of fault bits is a(y) and b(y), the difference d|_{a,b}=|a(y)−b(y)|.

The processor 21 adds one to the histogram H(d) related to the difference value d (Step 4). For example, if d=3, the histogram H(3) increases by “1.” The histogram H(d) is updated and stored in the memory 22.

After Step 4, the processor 21 judges whether or not all pairs of the fault bits are processed in the Steps 3 and 4 (Step 5). If all pairs of the fault bits are not processed, then the processor 21 goes back to Step 3. Thus the processor 21 repeatedly executes the Steps 3 and 4 until all pairs of the fault bits are completely processed, As the result of the repeat, the histograms H(d), namely the difference emergence values, indicate the numbers of times the difference values “d” emerge in the calculation results of the Step 3.

If all pairs of the fault bits are completely processed, then the processor 21 goes to Step 6, and derives an expectation function T(f) from all of the histograms H(d). The expectation function T(f) represents a distribution of the fault bits and comprises, as factors, divisors included in each of the difference values “d” corresponding to the histograms H(d).

To derive the expectation function T(f), the method of this embodiment utilizes the manner disclosed in the foregoing Japanese Unexamined Publication No. 2000-200814. The expectation function T(f) is defines as:

T(f)=f Σm(f)/(N−-ux)

where:

Σm(f) is the number of combinations of the fault bits, each of the combinations resulting in the difference value that has “f” as a divisor;

N is the total number of the combinations of the fault bits; and

ux is the number of the combinations of the fault bits, each of the combinations resulting in the difference value that is equal to zero. In this embodiment, ux is equal to H(O).

Provided that the number of the fault bits is “n,” the total number of the combinations of the fault bits “N” is ₙC₂. That is, N=n×(n−1)/2. Provided that the maximum one of the difference values is “max(d)” and that a counter value is “j,” the difference value “d” is represented by “fj” and the define of the expectation function T(f) is modified as:

$$T ( f ) = \frac{2 f}{n ( n - 1 ) - 2 H ( 0 )} \times \sum H ( fj )$$

where the range of the summation ΣH(fj) is from j=1 to j=a certain number “k” that meets fj≦max(d), namely

$${\sum }_{j = 1}^{k} H ( fj ) .$$

After the derivation of the expectation function T(f) according to the define as described above, the processor 21 judges whether or not the distribution of the fault bits has a regular profile, on the basis of the expectation function (Step 7).

If the distribution of the fault bits has a regular profile, the processor 21 goes to Step 8, and calculates a period of the regular profile on the basis of the expectation function T(f). If the distribution of the fault bits does not have a regular profile, the processor 21 does not execute any process and the analysis ends.

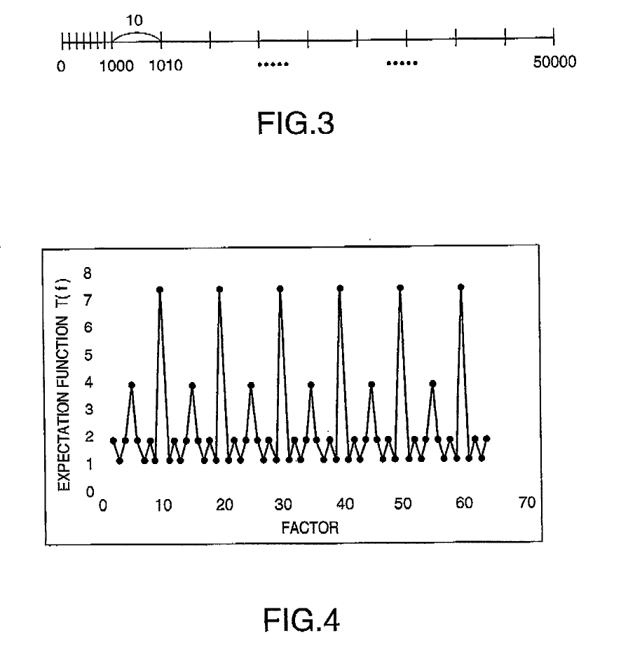

As one example, FIG. 3 shows the one-dimensional distribution of the fault bits. In the example of the distribution, the fault bits exist on every coordinate positions between the position “0” and the position “1000.” Also the fault bits exist on every ten positions between the position “1000” and the position “50000.” The total number of the fault bits is 5900.

The processor 21 reads, out of the memory 11, the bitmap data corresponding to the one-dimensional distribution of the fault bits, and derives the expectation function T(f) shown in FIG. 4. The illustrated expectation function T(O is obtained by considering that the range of the factor “f” is from two to sixty four. Then the processor 21 judges that the illustrated expectation function T(f) has a regular profile, and computes the period of the regular profile at ten, on the basis of the expectation function T(f).

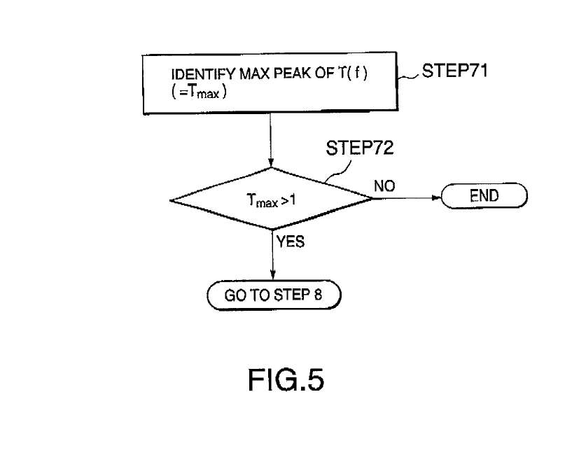

Now, explanation will be made about concrete examples of this embodiment, with reference to FIGS. 5 through 9. In particular, the concrete examples relate to the Steps 7 and 8 in FIG. 2.

In the first example, the expectation function has the plurality of peaks, and the processor 21 uses the maximum peak when judging whether or not the distribution of the fault bits has a regular profile.

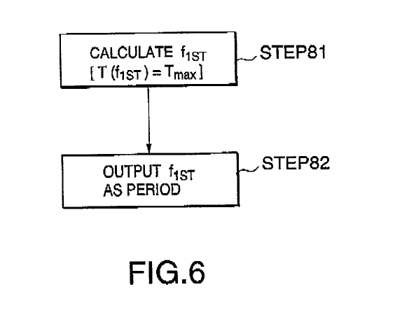

Referring to FIG. 5, the processor 21 identifies the maximum peak among the peaks of the expectation function T(f in Step 71. The maximum peak is represented by Tₘₐₓ. After the identification, the processor 21 judges whether or not Tₘₐₓ is greater than one (Tₘₐₓ>1). As the result of the judgment, if the maximum peak Tₘₐₓ is greater than one, the processor 21 recognizes that the distribution has the regular profile (Step 71), and goes to Step 81 of FIG. 6. In example of FIG. 4, the maximum peak Tₘₐₓ is 7.2072 and is greater than 1, so that the processor 21 recognizes that the distribution has the regular profile.

In Step 81 of FIG. 6, the processor 21 calculates a first factor f₁ₛₜ which causes the expectation function T(f) to have the maximum peak Tₘₐₓ, namely T(f₁ₛₜ)=Tₘₐₓ. Then the processor 21 outputs the first factor f₁ₛₜ as the period of the regular profile. That is, the processor 21 computes the period of the regular profile at the factor f₁ₛₜ which causes the expectation function T(f) to have the maximum peak Tₘₐₓ. In the example of FIG. 4, the first factor f₁ₛₜ is ten so that the processor 21 outputs “ten” as the period of the regular profile.

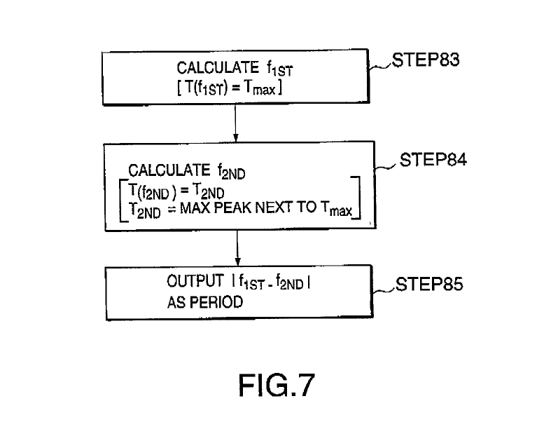

The second example is the modification of the above-mentioned first example. In the second example, the calculation of the period of the regular profile is carried out as shown in FIG. 7 instead of FIG. 6.

In detail, the processor 21 calculates a first factor f₁ₛₜ corresponding to Tₘₐₓ (Step 83). That is, the Step 83 of FIG. 7 is the same step as the Step 81 of FIG. 6. Then the processor 21 finds out a next maximum peak among the peaks of the expectation function T(f). The next maximum peak is a maximum peak next to the maximum peak Tₘₐₓ, and is represented by T_{2nd}. The processor 21 obtains a second factor f_{2nd} which causes the expectation function T(f) to have the next maximum peak T_{2nd}, that is, T(f_{2nd})=T_{2nd} (Step 84). The processor 21 calculates an absolute value of a difference between the first factor f₁ₛₜ and the second factor f_{2nd}, that is, |f₁ₛₜ−f_{2nd}|. Then the processor 21 outputs the absolute value |f₁ₛₜ−f_{2nd}| as the period of the regular profile (Step 85). In other-words, the processor 21 computes the period of the regular profile at the absolute value |f₁ₛₜ−f_{2nd}|. In the example of FIG. 4, when the second factor f_{2nd} is twenty (f_{2nd}=20), the expectation function T(f) is the next maximum peak T_{2nd}, 7.2072 (T_{2nd}=7.2072). Since the first factor f₁ₛₜ is ten, the period of the regular profile is ten.

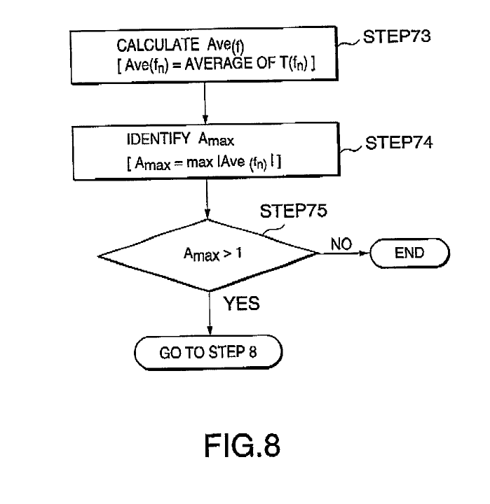

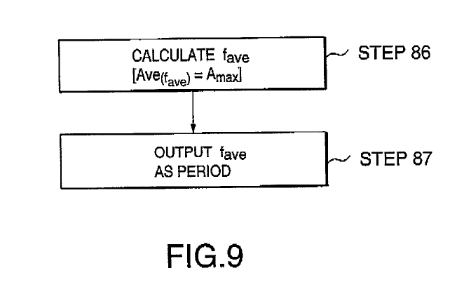

In the third example, the processor 21 performs the Steps 7 and 8, as shown in FIGS. 8 and 9.

In Step 73 of FIG. 7, the processor 21 averages the expectation function T(f) at each of the factors “f” so as to obtain average values Ave(f). Provided that a counter value is “j,” the average value Ave(f) is expressed by the following equation:

$$Ave ( f ) = \frac{1}{[ max ( f ) / f ]} \times \sum T ( fj )$$

where the range of the summation ΣT(fj) is from j=1 to j=[max(f)/f], namely

$${\sum }_{J = 1}^{\{ max ( f ) / f \}} T ( fj ) .$$

The [max(f)/f] is the greatest integer that does not exceed max(f)/f. In the example of FIG. 4, the maximum value of the factors is sixty four. In this case, Ave(2) and Ave(3) take the following values:

$$Ave ( 2 ) = \frac{1}{32} ( T ( 2 ) + T ( 4 ) + T ( 6 ) + … + T ( 64 ) )$$

$$Ave ( 3 ) = \frac{1}{21} ( T ( 3 ) + T ( 6 ) + T ( 9 ) + … + T ( 63 ) )$$

Similarly, Ave(4) through Ave(64) are calculated in the Step 73.

Then the processor 21 identifies the maximum one of the average values (Step 74). The maximum average value is represented by “Aₘₐₓ.” In the example of FIG. 4, Aₘₐₓ is Ave(10),

$$Ave ( 10 ) = \frac{1}{6} ( T ( 10 ) + T ( 20 ) + … + T ( 60 ) ) = 7.203 = {A}_{max}$$

The processor 21 judges whether or not the maximum average value Aₘₐₓ is greater than one (A_{max>}1). As the result of the judgment, if the maximum average value Aₘₐₓ is greater than one, the processor 21 recognizes that the distribution of the fault bits has the regular profile, and goes to Step 86 of FIG. 9. In the example of FIG. 4, the maximum average value Aₘₐₓ is 7.203 and is greater than one, so that the processor 21 recognizes that the fault bit distribution has the regular profile.

In Step 86 of FIG. 9, the processor 21 obtains a predetermined factor fₐᵥₑ which causes the average function of Ave(f) to have the maximum average value Aₘₐₓ, namely, Ave(fₐᵥₑ)=Aₘₐₓ. Then the processor 21 outputs the predetermined factor fₐᵥₑ as the period of the regular profile. That is, the processor 21 computes the period of the regular profile at the predetermined factor fₐᵥₑ which relates to the maximum average value Aₘₐₓ. In the example of FIG. 4, the predetermined factor fₐᵥₑ is ten so that the processor 21 outputs “ten” as the period of the regular profile.

The above-mentioned embodiment and modifications may be also implemented in a computer program product, as explained below.

On a practical level, the software that enables the computer system to perform the above-identified approach and operations of the invention is supplied on any one of variety of media. Furthermore, the actual implementation of the approach and operations of the invention are statements written in a programming language. Such programming language statements, when executed by a processor of a computer, cause the processor to act in accordance with the particular content of the statements. Furthermore, the software that enables a computer system to act in accordance with the invention may be provided in any forms including, but not limited to, original source code, assembly code, object code, machine language, compressed or encrypted versions of the foregoing, and any and all equivalents.

One of skill in the art will appreciate that “media”, or “computer-readable media”, as used here, may include not only the above-mentioned memory, such as an integrated circuit and a hard disk drive, but also a flexible disk, a tape, a compact disc, a magneto optical disc, an integrated circuit, a cartridge, a remote transmission via a communications circuit such as a LAN cable, or any other similar medium useable by computers. For example, to supply software for enabling a computer system to operate in accordance with the invention, the supplier might provide a diskette or might transmit the software in some form via the Internet.

Although the enabling software might be “written on” a diskette, “stored in” an integrated circuit, or “carried over” a communications circuit, it will be appreciated that, for the purpose of this application, the computer usable medium will be referred to as “bearing” the software. Thus, the term “bearing” is intended to encompass the above and all equivalent ways in which software is associated with a computer usable medium.

For the sake of simplicity, therefore, the term “program product” is thus used to refer to a computer useable medium, as defined above, which bears in any form of software to enable a computer system to operate in the fault analyzer according to the above-identified invention.

The invention is also embodied in a program product bearing software which enables a computer to operate in the forgoing fault analysis method.

The entire disclosure of Japanese Patent Application No. 2000-12753 filed on Jan. 21, 2000 including specification, claims, drawings and summary are incorporated herein by reference in its entirety.

What is claimed is:

1. A method of analyzing faults occurring in a semiconductor device, by the use of bitmap data produced as a test result by a tester which is for the semiconductor device and which comprises a first memory, the semiconductor device comprising circuitry elements which are arranged regularly in the semiconductor device and which correspond to bits having addresses in the bitmap data, respectively, the bitmap data being stored in the first memory of the tester and including fault bits which are the bits corresponding to the circuitry elements having the faults, the method being executed at a computer system including a second memory, the method comprising:
defining and initializing a plurality of difference emergence values, so that all of the difference emergence values have zeros as initial values and are stored in the second memory;
reading the bitmap data out of the first memory to write into the second memory coordinate values of all of the fault bits included in the bitmap data;
selecting a pair of the fault bits from all of the fault bits to calculate a difference value between the addresses of the pair of fault bits, with reference to the coordinate values written into the second memory;
adding one to the difference emergence value related to the difference value which is obtained as a result of the calculation in the selecting, so that the difference emergence value is updated and stored in the second memory;
repeatedly executing the selecting and the adding until all pairs of the fault bits are completely processed, so that the difference emergence values indicate the numbers of times the difference values emerge in calculation results in the selecting repeatedly executed; then
deriving from all of the difference emergence values an expectation function which represents a distribution of the fault bits;
judging, on the basis of the expectation function, whether or not the distribution of the fault bits has a regular profile; and
calculating a period of the regular profile on the basis of the expectation function when the distribution has the regular profile.

2. An analyzing method as claimed in claim 1, wherein;
the expectation function has a plurality of peaks; and
the judging comprises identifying a maximum peak among the peaks of the expectation function, so that the distribution is judged to have the regular profile when the maximum peak of the expectation function is greater than one.

3. An analyzing method as claimed in claim 2, wherein the expectation function comprises, as factors, divisors included in each of the difference values corresponding to difference emergence values, so that the calculating is carried out by the use of the factors of expectation function.

4. An analyzing method as claimed in claim 3, wherein the calculating comprises computing the period of the regular profile at a value of the factor which causes the expectation function to have the maximum peak.

5. An analyzing method as claimed in claim 3, wherein the calculating comprises:
obtaining a next maximum peak among the peaks of the expectation function, the next maximum peak being a maximum peak next to the maximum peak; and
computing the period of the regular profile at an absolute value of a difference between values of the factors which cause the expectation function to have the maximum peak and the next maximum peak, respectively.

6. An analyzing method as claimed in claim 1, wherein the judging comprising:
averaging each of values of the expectation function at each of the factors to obtain average values; and
identifying a maximum one of the average values,. so that the distribution is judged to have the regular profile when the maximum average value is greater than one.

7. An analyzing method as claimed in claim 6, wherein the calculating comprises computing the period of the regular profile at a value of the factor which relates to the maximum average value.

8. A fault analyzer which is adapted to analyze faults occurring in a semiconductor device, by the use of bitmap data produced as a test result by a tester which is for the semiconductor device and which comprises a memory, the semiconductor device comprising circuitry elements which are arranged regularly in the semiconductor device and which correspond to bits having addresses in the bitmap data, respectively, the bitmap data being stored in the memory of the tester and including fault bits which are the bits corresponding to the circuitry elements having the faults, said fault analyzer comprising:
a processor, and
a memory including software instructions adapted to enable said processor to cause the fault analyzer to perform:
defining and initializing a plurality of difference emergence values, so that all of the difference emergence values have zeros as initial values and are stored in the memory of the fault analyzer;
reading the bitmap data out of the first memory to write, into the memory of the fault analyzer, coordinate values of all of the fault bits included in the bitmap data;
selecting a pair of the fault bits from all of the fault bits to calculate a difference value between the addresses of the pair of fault bits, with reference to the coordinate values written into the memory of the fault analyzer;
adding one to the difference emergence value related to the difference value which is obtained as a result of the calculation in the selecting, so that the difference emergence value is updated and stored in the memory of the fault analyzer;
repeatedly executing the selecting and the adding until all pairs of the fault bits are completely processed, so that the difference emergence values indicate the numbers of times the difference values emerge in calculation results in the selecting repeatedly executed; then
deriving from all of the difference emergence values an expectation function which represents a distribution of the fault bits;
judging, on the basis of the expectation function, whether or not the distribution of the fault bits has a regular profile; and
calculating a period of the regular profile on the basis of the expectation function when the distribution has the regular profile.

9. A fault analyzer as claimed in claim 8, wherein:
the expectation function has a plurality of peaks; and
the memory of the fault analyzer further includes software instructions adapted to enable the fault analyzer further to perform the judging so as to include identifying a maximum peak among the peaks of the expectation function, so that the distribution is judged to have the regular profile when the maximum peak of the expectation function is greater than one.

10. A fault analyzer as claimed in claim 9, wherein the expectation function comprises, as factors, divisors included in each of the difference values corresponding to difference emergence values, so that the calculating is carried out by the use of the factors of expectation function.

11. A fault analyzer as claimed in claim 10, wherein the memory of the fault analyzer further includes software instructions adapted to enable the fault analyzer further to perform the calculating so as to include computing the period of the regular profile at a value of the factor which causes the expectation function to have the maximum peak.

12. A fault analyzer as claimed in claim 10, wherein the memory of the fault analyzer further includes software instructions adapted to enable the fault analyzer further to perform the calculating so as to include:
obtaining a next maximum peak among the peaks of the expectation function, the next maximum peak being a maximum peak next to the maximum peak; and
computing the period of the regular profile at an absolute value of a difference between values of the factors which cause the expectation function to have the maximum peak and the next maximum peak, respectively.

13. A fault analyzer as claimed in claim 8, wherein the memory of the fault analyzer further includes software instructions adapted to enable the fault analyzer further to perform the judging so as to include:
averaging each of values of the expectation function at each of the factors to obtain average values; and
identifying a maximum one of the average values, so that the distribution is judged to have the regular profile when the maximum average value is greater than one.

14. A fault analyzer as claimed in claim 13, wherein the memory of the fault analyzer further includes software instructions adapted to enable the fault analyzer further to perform the calculating so as to include computing the period of the regular profile at a value of the factor which relates to the maximum average value.

15. A computer program product for use in a computer system comprising a processor and a memory, the computer program product being for enabling a processor to perform as a fault analyzer which is adapted to analyze faults occurring in a semiconductor device, by the use of bitmap data produced as a test result by a tester which is for the semiconductor device and which comprises a memory, the semiconductor device comprising circuitry elements which are arranged regularly in the semiconductor device and which correspond to bits having addresses in the bitmap data, respectively, the bitmap data being stored in the memory of the tester and including fault bits which are the bits corresponding to the circuitry elements having the faults, said computer program product comprising:
software instructions for enabling the processor to perform predetermined operations, and
a computer readable medium bearing the software instructions:
the predetermined operations including:
defining and initializing a plurality of difference emergence values, so that all of the difference emergence values have zeros as initial values and are stored in the memory of the computer system;
reading the bitmap data out of the first memory to write, into the memory of the computer system, coordinate values of all of the fault bits included in the bitmap data;
selecting a pair of the fault bits from all of the fault bits to calculate a difference value between the addresses of the pair of fault bits, with reference to the coordinate values written into the memory of the computer system;
adding one to the difference emergence value related to the difference value which is obtained as a result of the calculation in the selecting, so that the difference emergence value is updated and stored in the memory of the computer system;
repeatedly executing the selecting and the adding until all pairs of the fault bits are completely processed, so that the difference emergence values indicate the numbers of times the difference values emerge in calculation results in the selecting repeatedly executed; then
deriving from all of the difference emergence values an expectation function which represents a distribution of the fault bits;
judging, on the basis of the expectation function, whether or not the distribution of the fault bits has a regular profile; and
calculating a period of the regular profile on the basis of the expectation function when the distribution has the regular profile.

16. A computer program product as claimed in claim 15, wherein:
the expectation function has a plurality of peaks; and
the judging is performed so as to include identifying a maximum peak among the peaks of the expectation function, so that the distribution is judged to have the regular profile when the maximum peak of the expectation function is greater than one.

17. A computer program product as claimed in claim 16, wherein the expectation function comprises, as factors, divisors included in each of the difference values corresponding to difference emergence values, so that the calculating is carried out by the use of the factors of expectation function.

18. A computer program product as claimed in claim 17, wherein the calculating is performed so as to include computing the period of the regular profile at a value of the factor which causes the expectation function to have the maximum peak.

19. A computer program product as claimed in claim 17, wherein the calculating is performed so as to include:
obtaining a next maximum peak among the peaks of the expectation function, the next maximum peak being a maximum peak next to the maximum peak; and
computing the period of the regular profile at an absolute value of a difference between values of the factors which cause the expectation function to have the maximum peak and the next maximum peak, respectively.

20. A computer program product as claimed in claim 15, wherein the judging is performed so as to include:
averaging each of values of the expectation function at each of the factors to obtain average values; and
identifying a maximum one of the average values, so that the distribution is judged to have the regular profile when the maximum average value is greater than one.

21. A computer program product as claimed in claim 20, wherein the calculating is performed so as to include computing the period of the regular profile at a value of the factor which relates to the maximum average value.

22. A method of analyzing faults occurring in a semiconductor device, by the use of bitmap data produced as a test result by a tester which is for the semiconductor device, the semiconductor device comprising circuitry elements which are arranged regularly in the semiconductor device and which corresponds to bits in the bitmap data, respectively, the bitmap data including fault bits which are the bits corresponding to the circuitry elements having the faults, the method comprising:
setting up, by the use of the bitmap data produced by the tester, an expectation function which represents a distribution of the fault bits and which has factors including a predetermined factor;
judging, on the basis of the expectation function, whether or not the distribution of the fault bits has a regular profile; and
calculating a period of the regular profile on the basis of the predetermined factor, when the distribution has the regular profile.
